(19) United States
(12) Patent Application Publication
(10) Pub. No.: US 2009/0294809 A1
(43) Pub. Date: Dec. 3, 2009

(54) REDUCTION OF METAL SILICIDE DIFFUSION IN A SEMICONDUCTOR DEVICE BY PROTECTING SIDEWALLS OF AN ACTIVE REGION

(76) Inventors: Kai Frohberg, Niederau (DE); Uwe Griebenow, Markkleeberg (DE); Frank Feustel, Dresden (DE); Thomas Werner, Reichenberg (DE)

Correspondence Address: WILLIAMS, MORGAN & AMERSON, 10333 RICHMOND, SUITE 1100, HOUSTON, TX, 77042, US

(21) Appl. No.: 12/390,544

(22) Filed: Feb. 23, 2009

(30) Foreign Application Priority Data
May 30, 2008 (DE) 10 2008 026 214.5

(51) Int. Cl. H01L 29/43; H01L 21/441

(52) U.S. Cl. 257/288; 438/584; 257/E29.139; 257/E21.477

(57) ABSTRACT

By protecting sidewall portions of active semiconductor regions during a silicidation process, the probability of creating nickel silicide pipes may be reduced. Consequently, yield losses caused by the shorting of PN junctions in sophisticated semiconductor devices may be reduced.

### BACKGROUND OF THE INVENTION

1. Field of the Invention

The present disclosure relates to the field of semiconductor manufacturing, and, more particularly, to contact areas of transistors that connect to a contact element of the contact level of the transistor.

2. Description of the Related Art

Semiconductor devices, such as advanced integrated circuits, typically contain a large number of circuit elements, such as transistors, capacitors and the like, which are usually formed in a substantially planar configuration on an appropriate substrate having formed thereon a crystalline semiconductor layer. Due to the large number of circuit elements and the required complex layout of modem integrated circuits, the electrical connections of the individual circuit elements may generally not be established within the same level on which the circuit elements are manufactured, but require one or more additional “wiring” layers, which are also referred to as metallization layers. These metallization layers generally include metal-containing lines, providing the inner-level electrical connection, and also include a plurality of inter-level connections, which are also referred to as “vias,” that are filled with an appropriate metal and provide the electrical connection between two neighboring stacked metallization layers.

To establish the connection of the circuit elements to the metallization layers, an appropriate contact structure is provided that connects to a respective contact region of a circuit element, such as a gate electrode and the drain/source regions of transistors, and to a respective metal line in the first metallization layer. The vertical contact structure, including a plurality of contacts or contact plugs, is formed in an inter-layer dielectric material that encloses and passivates the circuit elements.

The continuing shrinkage of dimensions of circuit elements, such as transistors, has been, and will remain, a major goal of semiconductor manufacturers, since significant gain in performance of semiconductor devices may be accomplished in terms of operating speed, production costs and the like. For example, the gate length of field effect transistors has now reached 0.05 μm and less, and, hence, fast and powerful logic circuitry, such as micro-processors, storage devices and the like, may be formed on the basis of these transistors, due to increased packing density, thereby also providing the possibility of incorporating more and more functions into a single die region. For instance, the amount of storage incorporated into modern CPUs has steadily increased, thereby enhancing overall performance of micro-processors. In other cases, complex analog and digital circuitry may be provided on the same semiconductor chip, thereby offering enhanced control functionality for a plurality of electronic devices. Upon reducing the feature sizes of the semiconductor circuit elements in the device level, however, the dimensions of the metal lines and vias in the wiring level of the semiconductor devices also have to be reduced, since the contact areas of the circuit elements have to be connected to the metallization level so that at least the contact structure and lower-lying metallization levels may also require a significant reduction in size of the individual metal lines and vias.

It should be appreciated that, for highly scaled semiconductor devices, typically, electrical performance of the metallization system including the contact level has a significant influence on the overall performance of the semiconductor device due to parasitic capacitance and the parasitic resistivity of the metal features. Consequently, in modem semiconductor devices, highly conductive metals, such as copper and the like, frequently may be used in combination with dielectric materials of reduced permittivity in order to restrict signal propagation delay caused by the metallization system. On the other hand, in the device level, a reduction of the channel length of field effect transistors in combination with very high dopant concentrations in the drain and source regions and gate electrodes, which may be comprised of polysilicon, may be used in view of reducing the overall series resistance of the individual circuit elements. However, in order to further reduce the series resistance of transistor devices and other circuit elements in the device level, the resistivity of highly doped silicon-based semiconductor areas is typically reduced by incorporating an appropriate metal species, for instance in the form of a metal silicide. The corresponding metal silicide may have a reduced sheet resistivity compared to even highly doped semiconductor materials, and hence a respective manufacturing sequence is typically incorporated in sophisticated process techniques in order to form appropriate metal silicide regions in the drain and source areas or other contact areas of circuit elements, possibly in combination with providing a respective metal silicide in the polysilicon gate electrodes.

Recently, well-approved metal silicides in the form of cobalt disilicide, are increasingly being replaced by metal silicide components of enhanced conductivity, such as nickel silicide. Although significant performance advantages may be associated with the incorporation of a nickel silicide into the drain and source areas of the transistors, it turns out, however, that, in the manufacturing sequence for forming metal silicides in combination with contact elements, significant yield loss may be observed in view of contact failure, which may frequently be caused by short circuits between contact elements and the gate electrode structure or by shorting the PN junctions of the transistors in the drain and source areas.

With reference to FIGS. 1a-1c, a typical conventional process flow will now be described, in which a nickel silicide is formed in sophisticated transistor elements.

FIG. 1a schematically illustrates a cross-sectional view of a semiconductor device 100, such as a field effect transistor, which comprises a substrate 101, for instance, in the form of a silicon substrate, a silicon-on-insulator (SOI) substrate and the like. In the manufacturing stage shown, the transistor 100 comprises an active region 102, which is to be understood as a silicon-containing semiconductor region, in which appropriate dopant profiles may be established in order to obtain the desired transistor function. The active region 102 may be laterally enclosed by an isolation structure 103, which may typically be provided in the form of a silicon dioxide material, possibly in combination with other dielectric materials, such as silicon nitride and the like. The isolation region 103 may be provided in the form of shallow trench isolations, which may divide a basic semiconductor layer (not shown) in a plurality of active regions, such as the region 102, in and above which one or more circuit elements, such as transistors and the like, are to be formed. Furthermore, the transistor 100 may comprise a gate electrode structure 104, which may include a gate electrode material 104A in the form of polysilicon, which may be separated from the active region 102 by a gate insulation layer 104B. As previously indicated, a length of the gate electrode structure 104, i.e., in FIG. 1a, the horizontal extension of the gate electrode material 104A, may be approximately 50 nm and less in highly sophisticated applications. Furthermore, a spacer structure 105 may be formed on the sidewalls of the gate electrode structure 104 in accordance with overall process and device requirements. For example, the spacer structure 105 may comprise a silicon nitride material, possibly in combination with an etch stop liner (not shown), such as a silicon dioxide material. It should further be appreciated that the gate electrode structure 104 may also comprise a dielectric material on sidewalls of the gate electrode material 104A, depending on the overall process strategy. Furthermore, doped regions 106E may be formed in an upper portion of the active region 102 and may comprise a moderately high dopant concentration as may be required for the transistor 100. The doped regions 106E, which may also be referred to as drain and source extension regions, may define a channel region 108, in which a conductive channel may form upon application of an appropriate control voltage to the gate electrode material 104A during operation of the device 100.

The transistor 100 as shown in FIG. 1a may be formed in accordance with the following conventional process strategies. After providing the substrate 101 having formed thereon a silicon-based semiconductor layer, the isolation regions 103 may be formed, for instance, by well-established lithography, etch, deposition and planarization techniques. That is, respective trenches or openings may be formed in the semiconductor layer so as to extend to the specified depth. For instance, in an SOI configuration, the respective trenches may extend down to a buried insulating layer (not shown), thereby providing substantially complete electrical insulation of the active region 102 after filling the trenches with an appropriate dielectric material, such as silicon dioxide. In a bulk configuration, the isolation regions 103 may extend to any specific depth in accordance with design rules. Next, the gate electrode structure 104 may be formed by forming appropriate materials for the gate insulation layer 104B and the gate electrode material 104A, followed by an advanced patterning regime, including lithography, etching and the like. It should be appreciated that, typically, a plurality of cleaning processes may have to be incorporated into the overall process flow in order to appropriately condition the surface of the device according to the specific manufacturing stage. During respective etch and cleaning processes, a certain amount of material of exposed surface areas may also be removed, for instance, due to cleaning processes, resist removal processes and the like, wherein typically the silicon dioxide material of the isolation regions 103 may be removed with a higher rate compared to the material of the active region 102. Thus, a recess 103R may be created during the manufacturing process.

After forming the gate electrode structure 104, the drain and source extension regions 106E may be formed by ion implantation and the like, followed by a sequence of depositing a spacer layer and subsequently etching the same to provide the spacer structure 105. Upon removing excess material during this process sequence, for instance in the form of a corresponding silicon dioxide etch stop liner of the spacer structure 105, a certain degree of recessing may also occur in this manufacturing stage.

FIG. 1b schematically illustrates the transistor 100 in a further advanced manufacturing stage. As illustrated, the transistor 100 may comprise drain and source regions 106, in combination with the extension regions 106E, wherein nickel silicide regions 107 may be formed in a portion of the drain and source regions 106. Similarly, the gate electrode structure 104 may comprise a nickel silicide region 104C in an upper portion thereof.

The transistor 100 as shown in FIG. 1b may be formed by performing an implantation sequence using the gate electrode structure 104 and the spacer structure 105 as an implantation mask in order to obtain a desired lateral profile of the drain and source regions 106. It should be appreciated that the spacer structure 105 may comprise two or more individual spacer elements, possibly in combination with respective etch stop liners, if a more sophisticated lateral profile may be required. Furthermore, one or more anneal processes may be performed to activate at least a part of the dopant species incorporated during the preceding implantation processes and also to re-crystallize, at least to a significant degree, implantation-induced damage in the drain and source regions 106. It should be appreciated that the process sequence may also require a plurality of cleaning and etch steps, for instance for removing resist masks used during the implantation sequence, for forming additional spacer elements, if required, and the like. Consequently, the recessing of the region 103 may become more pronounced in this manufacturing stage. Moreover, the exposed surface portions of the device 100 may be prepared for the deposition of a nickel layer, which may also contribute to the final recessing of the isolation region 103. After the deposition of the nickel layer, an appropriate heat treatment may be performed to initiate a chemical reaction with the underlying crystalline silicon material, while a significant chemical reaction of the nickel and the dielectric areas, such as the spacer structure 105 and the isolation structure 103, may be suppressed. Thereafter, any non-reacted nickel may be removed on the basis of well-established selective etch recipes.

Thereafter, the further processing may be continued by depositing a dielectric material of the contact level so as to enclose and passivate the transistor 100, i.e., provide chemical and mechanical integrity of the transistor 100 for the further processing, i.e., the formation of metallization layers, as previously explained. The corresponding dielectric material may be patterned on the basis of sophisticated etch techniques to form respective contact openings connecting to the drain and source regions 106, i.e., to the corresponding nickel silicide regions 107, and also to the gate electrode structure 104, i.e., to the nickel silicide 104C. The contact openings may be filled with an appropriate metal, such as tungsten and the like.

As previously explained, although the nickel silicide regions 107, 104C may provide enhanced sheet resistivity, significant device failures may be observed, for instance caused by short circuits between the gate electrode structure 104 and a contact connecting to one of the drain and source regions 106 and/or by a shorting of the PN junction in the drain or source areas, wherein nickel silicide material 107A may extend from the drain or source regions 106 into the channel region 108.

Although the reason for respective short circuits, such as the nickel silicide areas 107A, which may also be referred to as nickel silicide pipe, is not yet fully understood, it is believed that the recesses 103R may contribute to undue nickel diffusion during the process sequence for forming the nickel silicide regions 107, as will be explained with reference to FIG. 1c.

FIG. 1c schematically illustrates a top view of the device 100. As shown, the recessed isolation region 103 encloses the active region 102, wherein the gate electrode structure 104 and the spacer structure 105 may be formed above the region 102. It is believed that, at an edge region 102E, the lattice structure of the silicon region 102 prior to the formation of the nickel silicide region 107 may be different, for instance due to crystal defects and the like, which may be caused by the preceding implantation processes, possibly in combination with other processes, which may result in a deteriorated lattice structure at sidewall portions of the edge region 102E. For example, implantation-induced damage in the drain and source regions 106 and the corresponding activation and re-crystallization may progress differently at the edge region 102E compared to inner areas, for instance due to a missing neighboring silicon material at the recess 103R and at the interface to the isolation region 103 and the like. As previously explained, upon deposition of the nickel layer, exposed sidewall portions of the active region 102 within the recess 103R (see FIG. 1b) may also be covered by nickel and thus be involved in the subsequent silicidation process. It is believed that, due to the disturbed lattice structure at the edge region 102E, an incomplete silicide formation may occur, thereby resulting in excess nickel, which may not be bonded to the silicon material and may thus undergo enhanced diffusion. Consequently, the respective nickel may diffuse and may come into contact with a substantially intact silicon lattice, in particular at critical areas 102C, in which the disturbed lattice structure of the edge region 102E may come into contact with a substantially undisturbed lattice provided below the spacer structure 105. The diffusing nickel atoms may thus react with the crystalline silicon material so as to form nickel silicide, which may result in the formation of the nickel silicide regions 107A (see FIG. 1b). Thus, if a sufficient amount of nickel may diffuse within the critical area 102C, a significant modification of the transistor behavior may result, or even a shorting of the corresponding PN junction may occur, as is shown in FIG. 1b.

Consequently, in particular in sophisticated semiconductor devices comprising densely spaced transistors, such as the transistor 100, the overall reduced dimensions may, therefore, result in a significant yield loss due to contact failures or short circuits caused by nickel silicide pipes, such as the region 107A, which may render nickel silicide a less attractive material for improving the overall sheet resistance despite the enhanced conductivity compared to, for instance, cobalt disilicide.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods in which a metal silicide, such as a nickel silicide, may be formed in advanced transistor devices such that a reduced probability of creating metal silicide short circuits in the drain and source areas, and also in the contact level, of the devices may be achieved. For this purpose, exposed sidewall portions of active semiconductor regions may be protected during the metal silicide formation sequence, thereby significantly reducing the amount of nickel or other metals which may be present in the edge region of the active region during the silicidation process. The protection of the exposed sidewalls may be accomplished, in some illustrative aspects, by forming a spacer element on exposed sidewalls of the active region, while, in other aspects, the recesses of the isolation region may be filled prior to the silicidation sequence. Consequently, yield losses during the critical silicide and contact formation process may be reduced.

One illustrative method disclosed herein comprises covering sidewalls of a silicon-containing active region of a semiconductor device by a silicide blocking material, wherein the active region is laterally enclosed by an isolation region that is recessed with respect to the active region. The method further comprises selectively forming a metal silicide on exposed portions of the silicon-containing active region while using the silicide blocking material as a mask.

A further illustrative method disclosed herein comprises forming a spacer element on sidewall portions of a silicon-containing active region of a semiconductor device. The method also comprises forming a metal silicide on an exposed portion of the silicon-containing active region while using the spacer element as a mask.

One illustrative semiconductor device disclosed herein comprises an isolation region formed above a substrate and a silicon-containing semiconductor region that is laterally enclosed by the isolation region, wherein the isolation region is recessed with respect to the silicon-containing semiconductor region. Moreover, the semiconductor device comprises a dielectric sidewall spacer formed on sidewalls of the silicon-containing semiconductor region. Finally, the semiconductor device comprises a metal silicide region formed on a portion of the active region, wherein the metal silicide region is in contact with the sidewall spacer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a transistor during various manufacturing stages according to conventional strategies in forming a nickel silicide;

FIG. 1c schematically illustrates a top view of the transistor having disturbed edge regions of the semiconductor material, according to the conventional strategy;

FIGS. 2a-2c schematically illustrate cross-sectional views of a semiconductor device during various manufacturing stages in forming a metal silicide, such as a nickel silicide, while protecting sidewall portions of an active region, according to illustrative embodiments;

FIG. 2d schematically illustrates a top view of the semiconductor device having the protected sidewall portions;

FIGS. 2e-2h schematically illustrate cross-sectional views of the semiconductor device according to still further illustrative embodiments, in which a protection of at least a significant portion of exposed sidewall surfaces may be accomplished by filling recesses prior to performing a silicidation sequence;

FIG. 2i schematically illustrates the deposition of a refractory metal, such as nickel, on an enhanced surface topography with refilled recesses, according to still other illustrative embodiments;

FIG. 2j schematically illustrates a cross-sectional view of the semiconductor device, in which exposed sidewall portions may be protected by a dielectric layer formed on the sidewall portions and on the isolation region, according to still further illustrative embodiments; and

FIG. 2k schematically illustrates the semiconductor device during a surface treatment, which may be used in enhancing protection of exposed sidewall portions of the active region, according to still other illustrative embodiments.

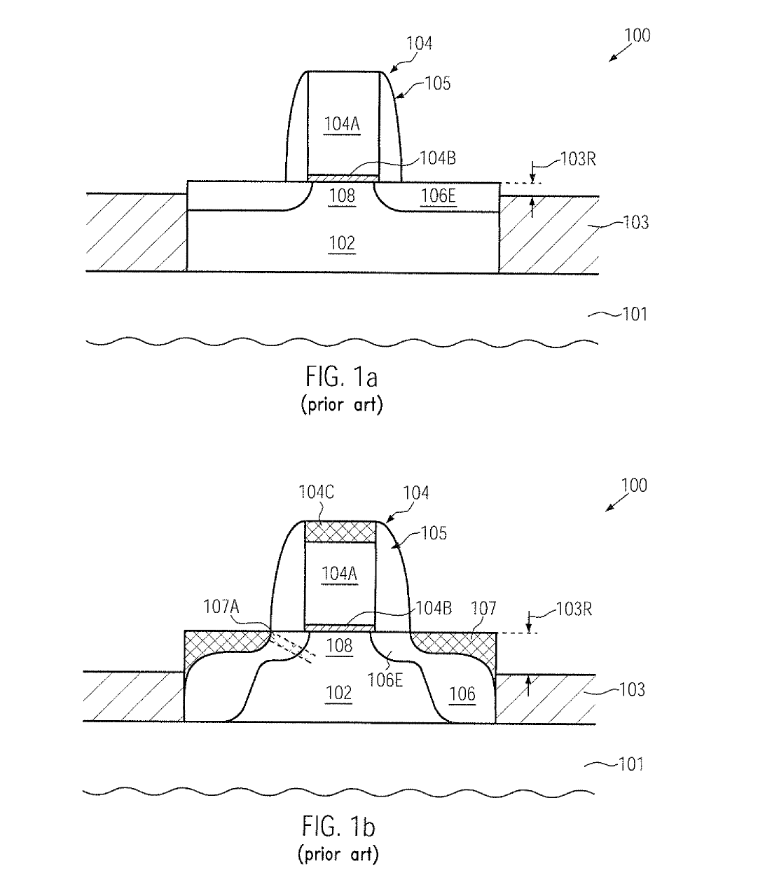

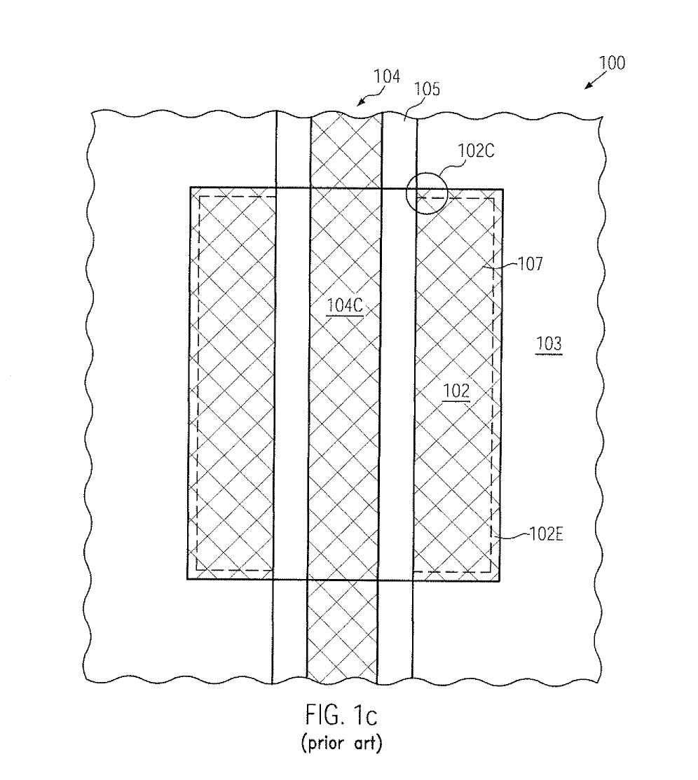

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and methods in which the silicidation mechanism at the edge of active regions of semiconductor devices may be substantially restricted to horizontal surface portions, thereby efficiently reducing the amount of “diffusible” metal atoms, which may diffuse into critical device areas. Without intending to restrict the present application to the following explanation, it is believed that by covering the sidewall surfaces, or at least portions thereof, of active semiconductor regions, the degree of diffusion of metal atoms into critical areas, such as the PN junction of the transistor elements, may be reduced. Thus, the reduced amount of diffusing metal atoms, such as nickel atoms, may also significantly reduce the probability of creating dislocated metal silicide protrusions, which may bridge the PN junction, since the overall amount of “damaged” silicon material at the edge of the active region, which may take part in the silicidation process, may be reduced.

An enhanced protection of at least a significant part of the exposed sidewall portions may be accomplished by forming an appropriate dielectric material, which may act as a silicide blocking material or a silicidation mask, while substantially not negatively affecting other device areas, such as exposed horizontal portions of the drain and source areas. The mask material may be provided in the form of a sidewall spacer element and/or as a cap layer extending from the sidewall portions of the active region into the isolation structures, while, in other cases, for at least temporarily, a fill material may be provided to enhance the sidewall protection and/or the formation of respective cap layers or spacer elements.

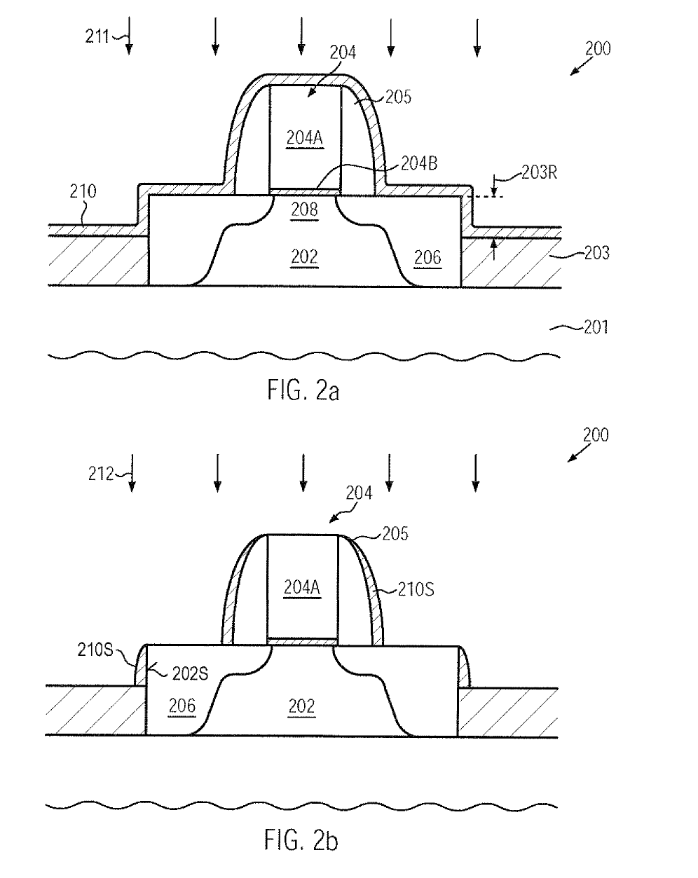

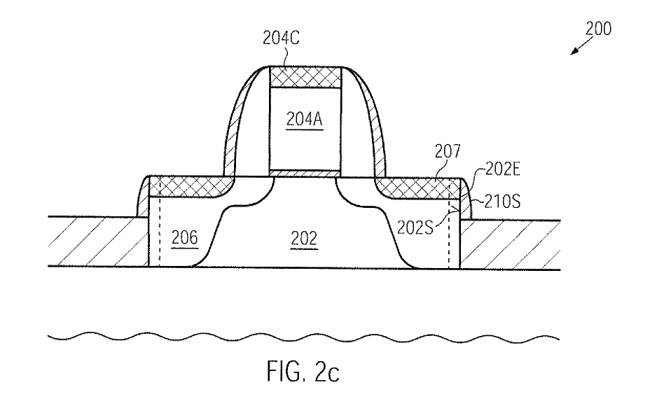

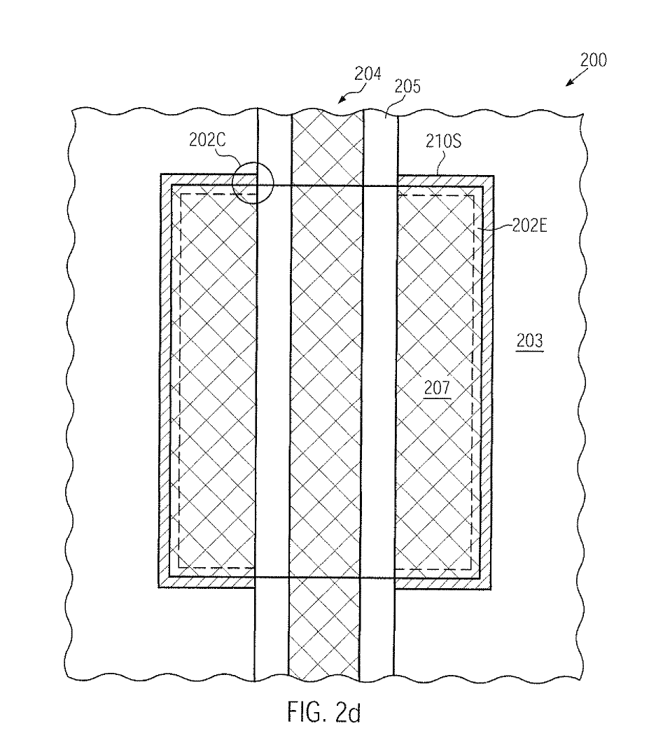

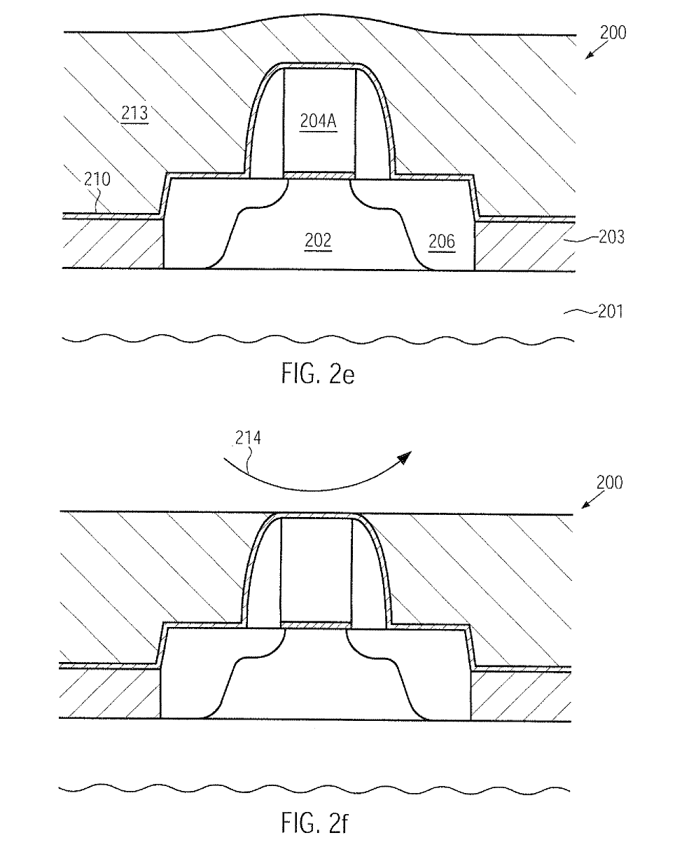

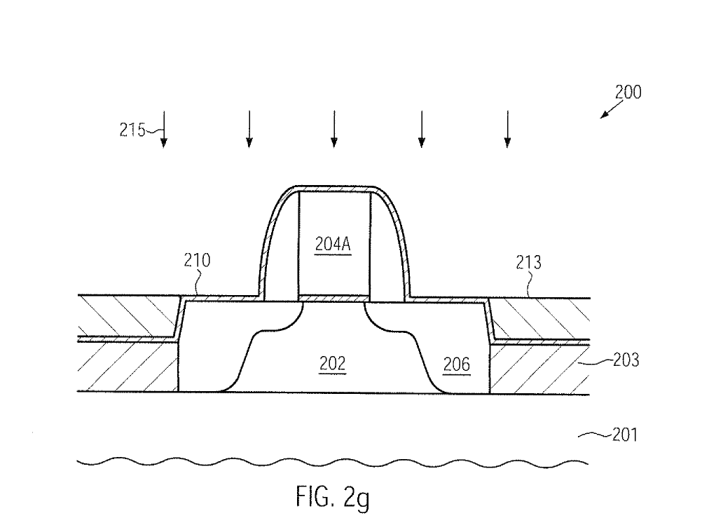

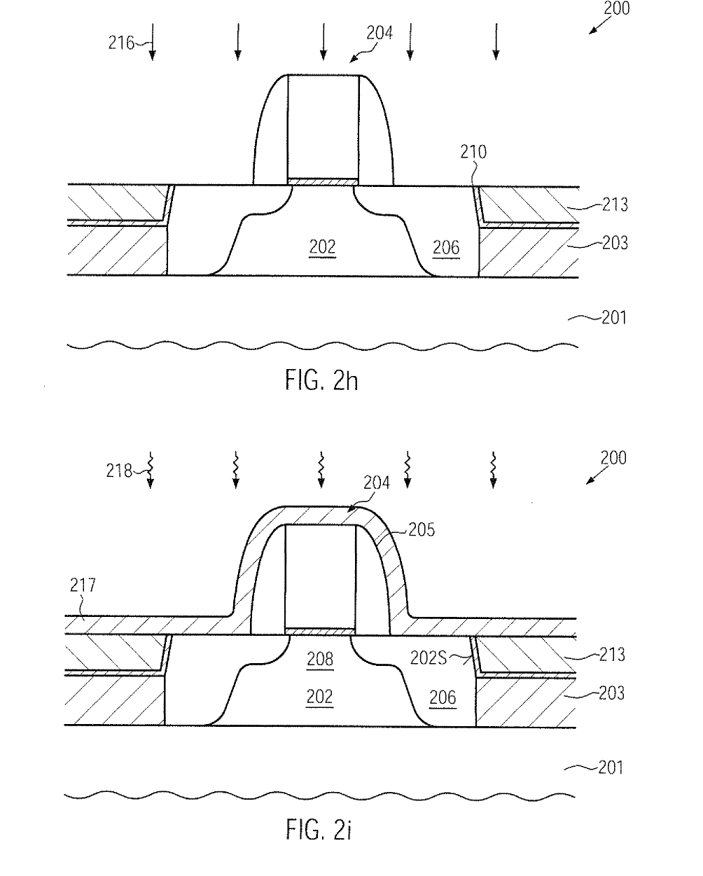

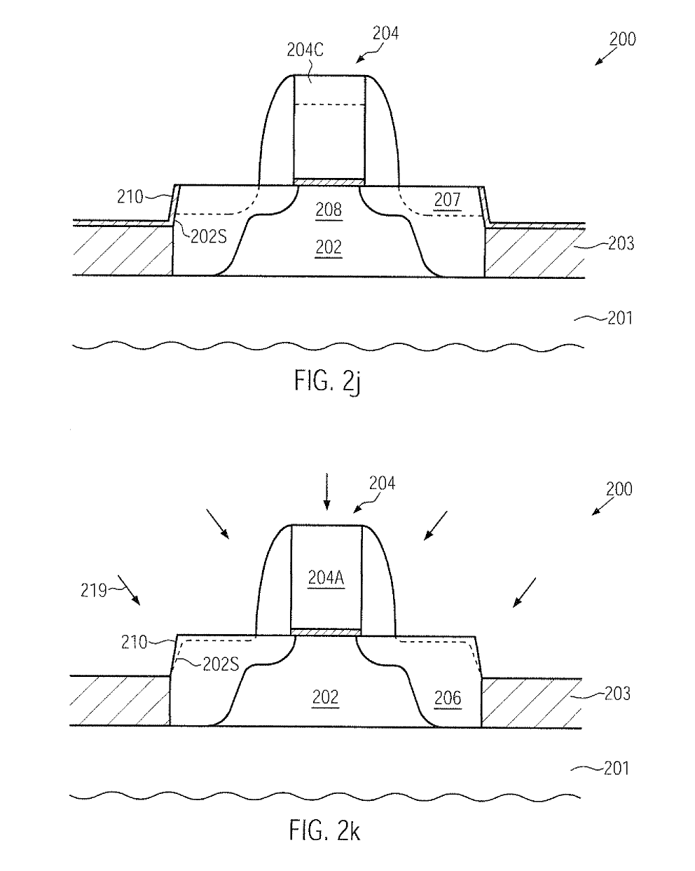

FIG. 2a schematically illustrates a cross-sectional view of a semiconductor device 200, which may comprise a substrate 201, above which may be formed an isolation region 203 that laterally encloses a silicon-containing semiconductor region 202. The substrate 201, in combination with the semiconductor region 202, may represent a bulk configuration. That is, the substrate 201 may comprise a silicon-based crystalline material directly connected to the semiconductor region 202, while, in other cases, an SOI configuration may be provided by the region 202 and the substrate 201, when the substrate 201 comprises a buried insulating layer (not shown) electrically isolating the region 202 in the vertical direction. The silicon-containing semiconductor region 202 may also be referred to as an active region, as previously explained. Furthermore, in the manufacturing stage shown, a gate electrode structure 204 may be formed above the active region 202, wherein a gate insulating layer 204B may separate a gate electrode 204A from a channel region 208. Furthermore, a spacer structure 205 may be formed on sidewalls of the gate electrode structure 204. The gate electrode 204A may be comprised of any appropriate electrode material, such as a metal-containing material, possibly in combination with polysilicon material and the like, as may be required by the overall device requirements. Similarly, the gate insulation layer 204B may be comprised of well-established materials, such as silicon dioxide, silicon nitride, silicon oxynitride and the like, while also high-k dielectric materials may be used, possibly in combination with conventional dielectrics, wherein a high-k dielectric material is to be understood as a dielectric material having a dielectric constant of 10 or higher. With respect to the overall device dimensions, the same criteria apply as previously explained. That is, a gate length of the gate electrode 204A may be in the range of 50 nm and less.

Furthermore, drain and source regions 206 may be formed in the active region 202, wherein a lateral and vertical dopant profile may be selected in accordance with design rules of the device 200. Furthermore, in the manufacturing stage shown, a spacer layer 210, for instance comprised of any appropriate dielectric material, such as silicon nitride, silicon carbide, nitrogen-enriched silicon carbide, silicon dioxide and the like, may be formed above the gate electrode structure 204, the active region 202 and within a recess 203R, which is formed by the isolation region 203 having a reduced height level with respect to the active region 202. That is, the surface of the isolation region 203 is below a height level as defined by the surface of the active region 202. It should be appreciated that a thickness of the spacer layer 210 may be selected such that a substantially conformal deposition behavior may be achieved. For example, the thickness of the layer 210 may range from approximately 10-50 nm or more, depending on the critical dimensions of the semiconductor device 200.

The semiconductor device 200 as shown in FIG. 2a may formed on the basis of well-established process techniques with respect to the components described so far, except for the spacer layer 210. That is, the gate electrode structure 204, the spacer structure 205 and the drain and source regions 206 may be formed in accordance with process techniques as previously described, wherein, also in this case, a significant recessing of the isolation region 203 may occur, as previously explained. Thereafter, the device 200 may be exposed to a deposition ambient 211, which may be any appropriate deposition process, such as a plasma enhanced chemical vapor deposition (CVD) process, a thermally activated CVD process and the like. For example, a plurality of process recipes are available for well-established dielectric materials, such as silicon dioxide, silicon nitride and the like. In one illustrative embodiment, the spacer layer 210 may be provided as a single material, such as a silicon nitride layer, silicon dioxide layer and the like, thereby providing reduced process complexity, while, in other cases, the layer 210 may comprise two or more layers, for instance in the form of an etch stop liner (not shown), followed by the actual spacer material. For instance, silicon dioxide in combination with silicon nitride may be formed during the deposition process 211, according to a desired sequence. For instance, silicon dioxide may be used as etch stop material and silicon nitride as the spacer material, while, in other cases, silicon nitride may be used as etch stop liner and silicon dioxide may be used as the actual spacer material. It should be appreciated that other material combinations may be used, depending on the overall strategy.

FIG. 2b schematically illustrates the semiconductor device 200 during an etch process 212, for instance performed according to an anisotropic etch recipe, for which well-established process parameter settings are available. Due to the anisotropic nature of the process 212, preferably the horizontal portions of the spacer layer 210 may be removed, while inclined portions or substantially vertical portions may be maintained, at least to a certain degree. Consequently, sidewall spacers 210S may be formed at sidewall portions 202S of the active region 202, which may cover in some embodiments at least 70% of the height of the portions 202S from bottom to top of the recess 203R (see FIG. 2a). Similarly, spacers 210S may be formed on portions of the spacer structure 205, having a moderately high inclination.

In other illustrative embodiments (not shown), the spacer structure 205 may be reduced in width, that is, one or more spacer elements formed therein may be removed, for instance on the basis of an appropriate etch stop liner, and the spacer layer 210 may be provided with an appropriate thickness so as to adjust a desired offset of a metal silicide region with respect to the gate electrode 204A in a later manufacturing stage. In this case, enhanced design flexibility may be accomplished, since the initial spacer structure 205 may act as an implantation mask for adjusting the lateral dopant profile of the drain and source regions 206, while, after removal thereof, or removal of a portion thereof, a desired lateral offset of the metal silicide regions may be adjusted on the basis of the spacer layer 210. For example, a reduced offset from the gate electrode 204A may be selected on the basis of the layer 210 in view of enhancing overall performance of the device 200, while at the same time the probability of increased yield losses due to PN junction shorting, for instance caused by metal diffusion, as previously explained, may be maintained at a low level due to the significantly reduced amount of nickel which may come into contact with the edge of the active region 202.

FIG. 2c schematically illustrates the semiconductor device 200 in a further advanced manufacturing stage. As illustrated, metal silicide regions 207, which in some illustrative embodiments may comprise a nickel metal, may be formed in the drain and source region 206 so as to connect to a portion of the spacer element 210S, wherein, however, contrary to the conventional approaches, the amount of metal silicide formed within an edge region 202E may be reduced due to the presence of the spacer elements 210S, which may suppress a direct contact of a refractory metal with the surface of the edge region along the entire recess 203R. Moreover, depending on the overall process strategy, a metal silicide region 204C may also be provided in the gate electrode 204A, when comprised of a silicon-containing material.

The metal silicide regions 207 may be formed in accordance with well-established process techniques, that is, by depositing a refractory metal, such as nickel, and initiating a chemical reaction by a heat treatment, wherein, however, the silicon metal inter-diffusion may be restricted to the horizontal surface portions of the drain and source regions 206, while a lateral diffusion via surface areas 202S may be restricted by the spacers 210S. Thereafter, any non-reacted metal may be removed according to well-established techniques, thereby also removing non-reacted metal from the spacers 210S.

FIG. 2d schematically illustrates a top view of the semiconductor device 200 after forming the metal silicide regions 207, 204C. As illustrated, the spacer 210S surrounds the edge region 202E, thereby reducing the depth of the metal silicide region 207 in the edge region 202E, as discussed above, which may thus restrict the amount of “diffusible” metal that may diffuse within the disturbed lattice structure of the edge region 202E. Consequently, the amount of “diffusible” metal atoms, such as nickel, within critical areas, such as the areas 202C, in which a disturbed lattice may contact a substantially intact lattice in the vicinity of the PN junction, may be restricted, and hence a reduced probability for accumulating sufficient metal silicide for causing a short circuit may be achieved. Consequently, yield losses caused by shorting the PN junctions may be significantly reduced.

FIG. 2e schematically illustrates the semiconductor device 200 according to further illustrative embodiments. As illustrated, the layer 210 may be provided with an appropriate thickness, for instance in the range of several nm to 20 or more nm, and may be comprised of any appropriate dielectric material, which, in some illustrative embodiments, may exhibit a high etch selectivity with respect to a fill material 213, which may be formed above the active region 202 and the isolation region 203. For example, in some illustrative embodiments, the fill material 213 may be maintained during the further processing of the device 200 and may be provided in the form of appropriate materials, such as silicon dioxide, silicon nitride and the like, wherein the layer 210 may provide a desired high etch selectivity, wherein respective material compositions are well-established in the art, as previously discussed. In other illustrative embodiments, the fill material 213 may represent a sacrificial material, which may be removed during the subsequent processing, as will be described later on in more detail. It should be appreciated that, in other illustrative embodiments, the layer 210 may be omitted, if a sufficient etch selectivity between the fill material 213 and the material of the active region 202, the gate electrode structure 204 and the spacer structure 205 is provided. For example, the fill material 213 may be provided in the form of silicon dioxide, which may be selectively removed with respect to silicon nitride, silicon and the like. The fill material 213 may be provided on the basis of any appropriate deposition technique, such as CVD, spin-on techniques, when polymer materials and the like are considered, wherein advantageously a highly non-conformal deposition characteristic may be applied during the corresponding deposition process.

FIG. 2f schematically illustrates the semiconductor device 200 during a planarization process 214, which may comprise a chemical mechanical polishing (CMP) process or any other planarization technique. During the process 214, the overall surface topography may be planarized, wherein, upon exposure of the gate electrode structure 204 or the layer 210 formed thereon, the process 214 may be stopped. In other cases, the planarization process 214 may be performed as a time-controlled process, without exposing the layer 210.

FIG. 2g schematically illustrates the device 200 during a selective etch process 215, which may be performed on the basis of plasma assisted recipes, wet chemical recipes, a combination thereof and the like. Due to the preceding planarization process 214, substantially uniform process conditions may be established during the etch process 215 such that, after stopping the process 215 upon exposing horizontal portions of the layer 210, a substantially planar surface topography with respect to the active region 202 and the isolation region 203 may be obtained. In other cases, as previously explained, the process 215 may be performed selectively with respect to material of the spacer structure 205 and the region 202, so that the layer 210 may be omitted.

FIG. 2h schematically illustrates the semiconductor device 200 during a further selective etch process, in which exposed portions of the layer 210 may be removed in order to prepare the device 200 for a subsequent silicidation process. For example, if the layer 210 may be comprised of silicon dioxide, silicon nitride and the like, well-established plasma assisted or wet chemical etch recipes are available and may be used in this case. Furthermore, the process 216 may include any cleaning steps, as required for appropriately preparing and conditioning the exposed surface portions of the active region 202 and possibly of the gate electrode structure 204. In other cases, the process 216 may represent a cleaning process without a reactive etch ambient when the layer 210 is not provided.

FIG. 2i schematically illustrates the device 200 during a silicidation process, in which a layer of refractory metal 217 is formed on exposed portions of the active region 202, the gate electrode structure 204, the spacer structure 205, and the fill material 213, possibly in combination with the residues of the layer 210. In some illustrative embodiments, the layer 217 may comprise a nickel material to provide enhanced conductivity, as previously explained, while, in other cases, other refractory metals, such as cobalt, platinum or combinations of two or more metals, may also be used. Due to the enhanced surface planarity created by the fill material 213, superior deposition conditions may be established during the deposition of the layer 217. Thereafter, a heat treatment 218 may be performed in order to initiate a chemical reaction, in which silicon material may react with the metal of the layer 217 to form a metal silicide, as previously explained. Thereafter, the further processing may be continued by removing non-reacted metal material from the spacer structure 205 and from the fill material 213. Next, if required, additional thermal treatments, for instance for stabilizing the characteristics of the metal silicide, may be performed. Also, in this case, a significantly reduced degree of metal diffusion may be accomplished due to the protection of at least portions of the sidewalls 202S of the active region 202.

Thereafter, the further processing may be continued, by depositing a further dielectric material, as previously explained. It should be appreciated that, in sophisticated applications, a dielectric material may be provided with a high internal stress level so as to create a respective strain in the channel region 208 of the device 200. For this purpose, the dielectric material provided after the silicidation may frequently be deposited with high internal stress, depending on the overall device requirements. Consequently, a respective sequence may also be applied to the device 200 after the silicidation sequence. In other illustrative embodiments, in addition to these strain-inducing mechanisms, the fill material 213 may be provided with a high internal stress level so that the remaining portions of the layer 213, as shown in FIG. 2i, may thus act on the drain and source regions 206 and finally on the channel region 208 to create a respective strain therein.

FIG. 2j schematically illustrates the semiconductor device 200 according to further illustrative embodiments, in which the fill material 213 may be removed, for instance prior to the silicidation process, in which then the layer 210 may protect the sidewalls 202S in order restrict undue silicide creation. In this case, the fill material 213 may provide enhanced process conditions during a selective removal of the layer 210 from horizontal portions of the active region 202, while maintaining the sidewalls 202S or at least portions thereof covered by the layer 210. For example, the fill material 213 may be provided in the form of a resist material, or a polymer material, which may be efficiently deposited on the basis of highly non-conformal deposition techniques and may then be appropriately etched with a high degree of uniformity so as to protect significant portions of the layer 210 at the sidewalls 202S during the etch process 216 (see FIG. 2h). In other illustrative embodiments, the fill material 213 may be removed after the silicidation process 207, in view of, for instance, enhanced stress transfer mechanisms, since a highly stressed dielectric material may be positioned in the recesses 203R, thereby further enhancing overall performance of the device 200.

FIG. 2k schematically illustrates the device 200 according to further illustrative embodiments, in which the layer 210 or a portion thereof, if two or more layers are to be provided for covering the sidewalls 202S, may be formed on the basis of a surface treatment 219. For example, the surface treatment 219 may include the incorporation of a desired species, such as oxygen, nitrogen and the like, into the material of the active region 202 so as to convert exposed portions of the region 202 in a silicide blocking material. For example, the surface treatment 219 may comprise an oxidation process, for instance in the form of a wet chemical oxidation, a plasma assisted oxidation, a thermally activated oxidation and the like. In other cases, nitrogen may be incorporated so as to form a nitride-like material, possibly in combination with oxygen, thereby also providing a high degree of silicide blocking effect. Consequently, the layer 210 may be provided in a selective manner wherein a moderately thin layer thickness of approximately 10 nm or less may be sufficient for achieving the desired silicide blocking effect. Thereafter, an anisotropic etch process may be performed to preferably remove the layer 210 from the horizontal portions, while maintaining at least a portion of the layer 210 at the sidewalls 202S. In other illustrative embodiments, in addition to the treatment 219, a further material layer may be deposited and may be patterned by an appropriate etch process; wherein the layer 210 formed by the surface treatment 219 may act as an efficient etch stop material.

Thereafter, the further processing may be continued, as previously described, thereby forming the metal silicide regions 207 (see FIG. 2j) while restricting silicide formation at the sidewalls 202S.

As a result, the present disclosure provides semiconductor devices and methods in which the degree of metal silicide formation at sidewalls of active regions may be restricted by protecting the sidewalls of an active region or at least a lower portion thereof during the silicidation process, thereby reducing the probability of metal diffusion into critical device areas. Consequently, yield losses due to shorting the PN junctions during the formation of metal silicide regions may be reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
covering at least a portion of sidewalls of a silicon-containing active region of a semiconductor device by a silicide blocking material, said active region being laterally enclosed by an isolation region that is recessed with respect to said active region; and
selectively forming a metal silicide on exposed portions of said silicon-containing active region while using said silicide-blocking material as a mask.

2. The method of claim 1, wherein covering at least a portion of said sidewalls of said silicon-containing active region comprises forming a spacer element on said sidewalls.

3. The method of claim 2, wherein forming said spacer element comprises forming a spacer layer and anisotropically etching said spacer layer.

4. The method of claim 3, wherein forming said spacer layer comprises depositing one or more material layers.

5. The method of claim 3, wherein forming said spacer layer comprises performing a surface treatment to modify at least exposed portions of said silicon-containing active region.

6. The method of claim 5, wherein performing said surface treatment comprises performing an oxidation process.

7. The method of claim 1, wherein covering at least a portion of said sidewalls of said silicon-containing active region comprises forming a fill material above said silicon-containing active region and said isolation region to obtain a substantially planar surface and removing said fill material to a depth to expose a surface of said silicon-containing active region.

8. The method of claim 7, wherein forming said fill material above said silicon-containing active region comprises forming an etch stop layer and depositing a dielectric material layer on said etch stop layer.

9. The method of claim 7, further comprising performing a planarization process prior to exposing said surface of said silicon-containing active region.

10. The method of claim 8, further comprising removing said dielectric material prior to forming said metal silicide.

11. A method, comprising:
forming a spacer element on sidewall portions of a silicon-containing active region of a semiconductor device; and
forming a metal silicide on an exposed portion of said silicon-containing active region while using said spacer element as a mask.

12. The method of claim 11, wherein a gate electrode structure is formed above a portion of said silicon-containing active region.

13. The method of claim 12, further comprising forming a metal silicide in said gate electrode structure.

14. The method of claim 11, wherein forming said spacer element comprises depositing a spacer material and anisotropically etching said spacer material.

15. The method of claim 14, further comprising performing an oxidation process.

16. The method of claim 11, wherein forming said spacer element comprises forming a first material layer and depositing a fill material so as to planarize a surface topography of said silicon-containing region and an isolation region laterally enclosing said silicon-containing active region.

17. The method of claim 16, further comprising removing a portion of said fill material so as to expose horizontal areas of said first material layer.

18. A semiconductor device, comprising:
an isolation region formed above a substrate;
a silicon-containing semiconductor region laterally enclosed by said isolation region, said isolation region being recessed with respect to said silicon-containing semiconductor region;
a dielectric sidewall spacer formed on sidewalls of said silicon-containing semiconductor region; and
a metal silicide region formed on a portion of said active region, said metal silicide region being in contact with said sidewall spacer.

19. The semiconductor device of claim 18, wherein said sidewall spacer is comprised of silicon and nitrogen containing material.

20. The semiconductor device of claim 18, wherein said metal silicide comprises nickel.

21. The semiconductor device of claim 18, further comprising a gate electrode structure formed above a portion of said silicon-containing semiconductor region.
